(19) United States
(12) Patent Application Publication
(10) Pub. No.: US 2025/0185494 A1
(43) Pub. Date: Jun. 5, 2025

(54) DISPLAY DEVICE

(71) Applicant: LG Display Co., Ltd., Seoul (KR)

(72) Inventor: Wonjin CHOI, Paju-si (KR)

(73) Assignee: LG Display Co., Ltd., Seoul (KR)

(21) Appl. No.: 18/799,684

(22) Filed: Aug. 9, 2024

(30) Foreign Application Priority Data
Dec. 4, 2023 (KR) 10-2023-0173356

(51) Int. Cl. H10K 59/80; H10K 59/35; H10K 59/38; H10K 59/88; H10K 77/10

(52) U.S. Cl. CPC H10K 59/8792; H10K 59/351; H10K 59/38; H10K 59/88; H10K 77/10

(57) ABSTRACT

Discussed is a display device including a reflection reduction layer having an open area corresponding to a light emitting area and a reflection prevention area outside of the open area, a buffer layer disposed on the reflection reduction layer, and an emission layer disposed on the buffer layer, and is capable of reducing the reflection of light.

### CROSS-REFERENCE TO RELATED APPLICATION

This application claims priority to Korean Patent Application No. 10-2023-0173356, filed on Dec. 4, 2023 in the Korean Intellectual Property Office, the entire contents of which is hereby expressly incorporated by reference into the present application.

### BACKGROUND

### Field

The present disclosure relates to electronic devices with a display, and more specifically, to display devices that can provide an improvement in reducing reflections.

### Discussion of the Related Art

With continued developments in technology and with the advent of information-oriented society, various needs for display devices for displaying images that provide information have increased. Recently, various types of display devices, such as liquid crystal display (LCD) devices, organic light emitting diode (OLED) display devices, and the like have been developed and widely used as effective displays to provide information.

The display device can include a polarizer that can prevent external light from being reflected from the display so that images displayed on the display devices can be perceived by a user more easily.

### SUMMARY OF THE DISCLOSURE

In a case where display devices include a polarizer, the polarizer can present a number of disadvantages.

For example, a low transmittance rate of the polarizer can increase a power consumption of the display devices which must compensate for the low transmittance rate of the polarizer. Further, the polarizer can be disadvantageous to be applied to flexible display devices due to thickness of the polarizer that can prevent the display from being made thinner. The application of the polarizer to display devices can substantially increase manufacturing costs of the display devices since a polarizer is often costly.

To address these issues, one or more aspects of the present disclosure can provide a display device capable of reducing the reflection of light without applying a polarizer.

One or more aspects of the present disclosure can provide a display device capable of reducing the reflection of light and ensuring visibility of a repair area without applying a polarizer.

One or more aspects of the present disclosure can provide a display device capable of being driven at low power as a polarizer with low transmittance is not applied.

According to one or more example embodiments of the present disclosure, a display device can be provided that includes a substrate including a light emitting area and a circuit area, a reflection reduction layer including an open area corresponding to the light emitting area and a reflection prevention area outside of the open area, a buffer layer disposed on the reflection reduction layer, and an emission layer disposed on the buffer layer.

According to one or more aspects of the present disclosure, the display device can further include a repair area disposed in the circuit area, and the reflection reduction layer can include a first part that is an outer area of the repair area, and a second part that corresponds to the repair area and is thinner than the first part.

According to one or more aspects of the present disclosure, the thickness of the buffer layer can be 0.5 micrometers or more. The thickness of the reflection reduction layer is 0.1 micrometer to 0.5 micrometer, and the transmittance of the reflection reduction layer corresponding to the repair area can be 50% or more.

According to one or more aspects of the present disclosure, the optical density of the reflection reduction layer corresponding to the repair area can be 0.1 to 0.6.

According to one or more aspects of the present disclosure, the optical density of the reflection reduction layer corresponding to the emission area of a first subpixel representing white color can be 0.1 to 0.6.

According to one or more aspects of the present disclosure, a display device can be provided that is capable of reducing the reflection of light without applying a polarizer.

According to one or more aspects of the present disclosure, a display device can be provided that is capable of reducing the reflection of light and ensuring visibility of a repair area without applying a polarizer.

According to one or more aspects of the present disclosure, a display device can be provided that is capable of being driven at low power as a polarizer with low transmittance is not applied.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to aspects of the present disclosure;

FIG. 2 illustrates an example display panel according to aspects of the present disclosure;

FIG. 3 is a cross-sectional view of a portion of an example display panel;

FIG. 4 is a cross-sectional view of an example portion of the display panel according to aspects of the present disclosure;

FIGS. 5 and 6 are cross-sectional views of an example repair area of the display panel according to aspects of the present disclosure;

FIGS. 7 and 8 are plan views illustrating an example reflection reduction layer included in the display panel according to aspects of the present disclosure;

FIG. 9 is a plan view illustrating an example portion of the display panel in which subpixels and repair areas are disposed according to aspects of the present disclosure;

FIG. 10 illustrates an example portion of the display panel in which subpixels and a repair area are disposed according to aspects of the present disclosure;

FIG. 11 is an example cross-sectional view of a repair area included in the display panel according to aspects of the present disclosure;

FIG. 12 is an example plan view illustrating a portion of a circuit area of a subpixel disposed in an active area of the display device according to aspects of the present disclosure; and

FIG. 13 is an example cross-sectional view taken along with line A-B of FIG. 12.

### DETAILED DESCRIPTION OF THE EMBODIMENTS

Reference will now be made in detail to example embodiments of the present disclosure, examples of which can be illustrated in the accompanying drawings. In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order, sequence or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, with reference to the accompanying drawings, various example embodiments of the present disclosure will be described in detail.

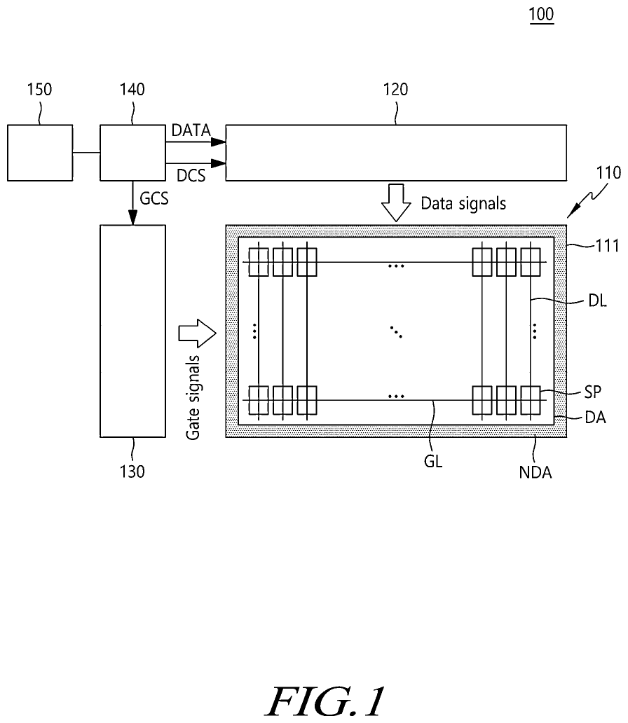

FIG. 1 illustrates an example system configuration of a display device 100 according to aspects of the present disclosure. All components of each display device according to all embodiments of the present disclosure are operatively coupled and configured.

Referring to FIG. 1, in one or more example embodiments, the display device 100 can include a display panel 110 and a display driving circuit as components for displaying an image. The display driving circuit can be a circuit for driving the display panel 110, and include a data driving circuit 120, a gate driving circuit 130, a display controller 140, and other circuit components.

The display panel 110 can include a substrate 111 and a plurality of subpixels SP disposed on the substrate 111.

The substrate 111 of the display panel 110 can include a display area DA allowing an image to be displayed and a non-display area NDA located outside of the display area DA.

A plurality of subpixels SP for displaying an image can be disposed in the display area DA, and the non-display area NDA can include a pad area PA located in a first direction from the display area DA.

In the display panel 110 according to aspects of the present disclosure, the non-display area NDA can have a very small area compared with the display area DA. Herein, the non-display area NDA can be also referred to as a “bezel” or a “bezel area.” But embodiments of the present disclosure are not limited thereto.

For example, the non-display area NDA can include a first non-display area located outside of the display area DA in a first direction, a second non-display area located outside of the display area DA in a second direction intersecting the first direction, a third non-display area located outside of the display area DA in a direction opposite to the first direction, and a fourth non-display area located outside of the display area DA in a direction opposite to the second direction. One or two non-display areas among the first to fourth non-display areas can include a pad area to which the data driving circuit 120 is connected or bonded. But embodiments of the present disclosure are not limited thereto. For example, among the first to fourth non-display areas, each of the remaining two or three non-display areas, which do not include the pad area, can have a very small size compared with the one or two non-display areas.

In an embodiment, a boundary area between the display area DA and the non-display area NDA can be bent, and thereby, the non-display area NDA can be located under the display area DA. In this implementation, when a user views the display device 100 in front thereof, all or most of the non-display area NDA may not be visible to the user.

Various types of signal lines for driving a plurality of subpixels SP can be disposed on the substrate 111 of the display panel 110.

In one or more aspects, the display device 100 can be a liquid crystal display device, or the like, or a self-emission display device in which light is emitted from the display panel 110 itself. In an example where the display device 100 according to aspects of the present disclosure is the self-emission display device, each of the plurality of subpixels SP can include a light emitting element. But embodiments of the present disclosure are not limited thereto.

For example, the display device 100 according to aspects of the present disclosure can be an organic light emitting display device implemented with organic light emitting diodes (OLED) as light emitting elements. In another example, the display device 100 according to aspects of the present disclosure can be an inorganic light emitting display device in which light emitting elements are implemented using inorganic material-based light emitting diodes (LED). In further another example, the display device 100 according to aspects of the present disclosure can be a quantum dot display device implemented with quantum dots, which are self-emission semiconductor crystals, as light emitting elements.

The structure of each of the plurality of subpixels SP can depend on types of display device 100. But embodiments of the present disclosure are not limited thereto. For example, when the display device 100 is a self-emission display device including self-emission subpixels SP, each subpixel SP can include a self-emission light emitting element, one or more transistors, and one or more capacitors.

The various types of signal lines can include, for example, a plurality of data lines DL for carrying data signals (which can be referred to as data voltages or image signals), a plurality of gate lines GL for carrying gate signals (which can be referred to as scan signals), and the like.

In one or more aspects, the plurality of data lines DL and the plurality of gate lines GL can intersect one another. Each of the plurality of data lines DL can be configured to extend in a first direction, and each of the plurality of gate lines GL can be configured to extend in a second direction. For example, the first direction can be the column or vertical direction, and the second direction can be the row or horizontal direction. In another example, the first direction can be the row or horizontal direction, and the second direction can be the column or vertical direction. But embodiments of the present disclosure are not limited thereto. Hereinafter, for convenience of explanation, discussions can be provided based on examples where each of a plurality of data lines DL is disposed in the column direction, and each of a plurality of gate lines GL is disposed in the row direction, but example embodiments of the present disclosure are not limited thereto.

The data driving circuit 120 can be a circuit for driving a plurality of data lines DL and can output data signals to the plurality of data lines DL.

The data driving circuit 120 can receive image data DATA in digital form from the display controller 140, convert the received image data DATA into data signals in analog form, and output converted data signals to the plurality of data lines DL.

In one or more aspects, the data driving circuit 120 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or implemented in the display panel 110 by a chip-on-film (COF) technique.

The data driving circuit 120 can be located in, and/or electrically connected to, but not limited to, only one side or portion (e.g., an upper edge or a lower edge) of the display panel 110. In one or more aspects, the data driving circuit 120 can be disposed in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or other design requirements.

The data driving circuit 120 can be connected to outside, or an edge, of the display area DA of the display panel 110, or be disposed in the display area DA of the display panel 110.

The gate driving circuit 130 can be a circuit for driving a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 can be embedded into the display panel 110 by a gate-in-panel (GIP) technique. In an example where the gate driving circuit 130 is implemented by the gate-in-panel (GIP) technique, the gate driving circuit 130 can be disposed on the substrate 111 of the display panel 110 during the manufacturing process of the display panel 110 or display device 100.

In one aspect, the gate driving circuit 130 included in the display device 100 can be disposed in the display area DA of the display panel 110. In this implementation, for example, the gate driving circuit 130 can be disposed in, and/or electrically connected to, but not limited to, a first area (e.g., a left area or a right area of the display area DA) of the display area DA of the display panel 110. In another example, the gate driving circuit 130 can be disposed in, and/or electrically connected to, but not limited to, a first area (e.g., a left area or a right area of the display area DA) and a second area (e.g., the right area or the left area of the display area DA) of the display area DA of the display panel 110. But embodiments of the present disclosure are not limited thereto.

Herein, the gate driving circuit 130 embedded in the display panel 110 using the gate-in-panel (GIP) technique can also be referred to as a “gate-in-panel circuit.”

The display controller 140 can be a device for controlling the data driving circuit 120 and the gate driving circuit 130, and can control driving timing for the plurality of data lines DL and driving timing for the plurality of gate lines GL.

The display controller 140 can supply a data driving control signal DCS to the data driving circuit 120 to control the data driving circuit 120, and supply a gate driving control signal GCS to the gate driving circuit 130 to control the gate driving circuit 130.

The display controller 140 can receive image data input from a host system 150 and supply image data DATA readable by the data driving circuit 120 based on the input image data to the data driving circuit 120.

The display controller 140 can be implemented in a separate component from the data driving circuit 120, or incorporated in the data driving circuit 120 and thus implemented in an integrated circuit.

The display controller 140 can be a timing controller used in the typical display technology or a controller or a control device capable of performing other control functions in addition to the function of the typical timing controller. In one or more embodiments, the display controller 140 can be a controller or a control device different from the timing controller, or a circuitry or a component included in the controller or the control device. The display controller 140 can be implemented using various circuits or electronic components such as an integrated circuit (IC), a field programmable gate array (FPGA), an application specific integrated circuit (ASIC), a processor, and/or the like.

The display controller 140 can be mounted on a printed circuit board, a flexible printed circuit, and/or the like and be electrically connected to the gate driving circuit 130 and the data driving circuit 120 through the printed circuit board, flexible printed circuit, and/or the like.

The display controller 140 can transmit signals to, and receive signals from, the data driving circuit 120 via one or more predefined interfaces. For example, such interfaces can include a low voltage differential signaling (LVDS) interface, an embedded clock point-point interface (EPI), a serial peripheral interface (SPI), and the like. However, example embodiments of the present disclosure are not limited thereto.

In one or more aspects, to provide a touch sensing function, as well as an image display function, the display device 100 can include a touch sensor, and a touch sensing circuit configured to sense the touch sensor and detect whether a touch is applied by an object such as a finger, a pen, or the like, or a location of the touch.

The touch sensing circuit can include a touch driving circuit configured to drive and sense the touch sensor and generate and output touch sensing data, and a touch controller capable of detecting whether a touch is applied or a location of the touch using the touch sensing data.

The touch sensor can include a plurality of touch electrodes. The touch sensor can further include a plurality of touch lines to electrically connect the plurality of touch electrodes to the touch driving circuit.

The touch sensor can be implemented in the form of a touch panel outside of the display panel 110 or be integrated inside of the display panel 110. In the example where the touch sensor is implemented in the form of the touch panel outside of the display panel 110, such a touch sensor can be referred to as an add-on type. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes can be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display device 100 can further include a power supply circuit for supplying various types of power to the display driving circuit and/or the touch sensing circuit.

In one or more aspects, the display device 100 can represent, but not limited to, a mobile terminal, such as a smart phone, a tablet, or the like, a monitor, a television (TV), or the like. Embodiments of the present disclosure are not limited thereto. In one or more aspects, the display device 100 can be display devices, or include displays, of various types, sizes, and shapes for displaying information or images.

In one or more example embodiments, the display device 100 can further include an electronic device such as a camera (e.g., an image sensor), a sensor capable of detecting an object, and the like. For example, the sensor can be a sensor capable of detecting an object or a human body by receiving light such as infrared light, ultrasonic light, ultraviolet light or the like. But embodiments of the present disclosure are not limited thereto.

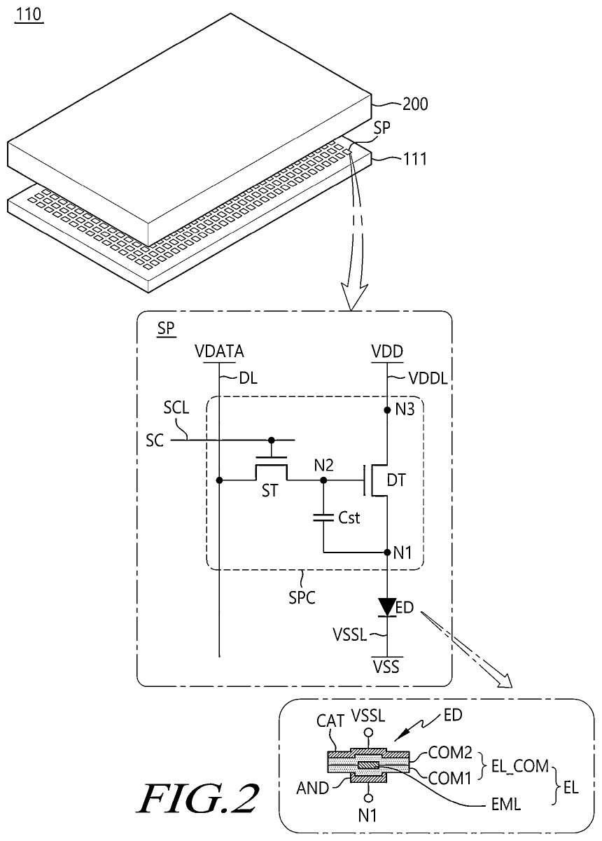

Referring to FIG. 2, in one or more example embodiments, the display panel 110 can include a substrate 111 on which a plurality of subpixels SP are disposed, and an encapsulation layer 200 over the substrate 111. The encapsulation layer 200 can also be referred to as an encapsulation substrate or an encapsulation stack.

Referring to FIG. 2, in an example where the display device 100 is a self-emission display device, each of the plurality of subpixels SP disposed on the substrate 111 can include a light emitting element ED and a subpixel circuit SPC for driving the light emitting element ED.

Referring to FIG. 2, the subpixel circuit SPC can include a plurality of pixel driving transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of pixel driving transistors can include a driving transistor DT for driving the light emitting element ED and a scan transistor ST configured to be turned on or off by a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a constant voltage during a display frame or a certain period of the display frame.

To drive one or more subpixels SP, at least one data signal VDATA, which is an image signal, and at least one scan signal SC, which is a gate signal, can be applied to one or more subpixels SP. Further, at least one common pixel driving voltage including a first common driving voltage VDD and a second common driving voltage VSS can be applied to the one or more subpixels SP.

The light emitting element ED can include an anode AND, a light emitting element intermediate layer EL, and a cathode CAT. The light emitting element intermediate layer EL can be disposed between the anode AND and the cathode CAT.

In an example where the light emitting element ED is an organic light emitting diode, the light emitting element intermediate layer EL can include an emission layer EML, a first common intermediate layer COM1 between the anode AND and the emission layer EML, and a second common intermediate layer COM2 between the emission layer EML and the cathode CAT. The emission layer EML can be disposed in each subpixel SP. The first common intermediate layer COM1 and the second common intermediate layer COM2 can be commonly disposed across all or some of a plurality of subpixels SP The emission layer EML can be disposed in each subpixel SP, and the first common intermediate layer COM1 and the second common intermediate layer COM2 can be commonly disposed across a plurality of light emitting areas and a non-light emitting area. A layer including the first common intermediate layer COM1 and the second common intermediate layer COM2 can be referred to as a common intermediate layer EL_COM.

For example, the first common intermediate layer COM1 can include a hole injection layer (HIL), a hole transfer layer (HTL), and the like. The second common intermediate layer COM2 can include an electron transport layer (ETL), an electron injection layer (EIL), and the like. The hole injection layer can inject holes from the anode AND to the hole transport layer, the hole transport layer can transport holes to the emission layer EML, the electron injection layer can inject electrons from the cathode CAT to the electron transport layer, and the electron transport layer can transport electrons to the emission layer EML. But embodiments of the present disclosure are not limited thereto.

For example, the cathode CAT can be electrically connected to a second common driving voltage line VSSL. A second common driving voltage VSS, which is a type of common pixel driving voltage, can be applied to the cathode CAT through the second common driving voltage line VSSL. The anode AND can be electrically connected to a first node N1 of a corresponding driving transistor DT of each subpixel SP. Herein, the second common driving voltage VSS can also be referred to as a “base voltage”, and the second common driving voltage line VSSL can also be referred to as a “base voltage line. But embodiments of the present disclosure are not limited thereto.

For example, the anode AND can be a pixel electrode layer disposed in each subpixel SP, and the cathode CAT can be a common electrode commonly disposed in a plurality of subpixels SP. In another example, the cathode CAT can be a pixel electrode layer disposed in each subpixel SP, and the anode AND can be a common electrode commonly disposed in a plurality of subpixels SP. Herein, for convenience of explanation, discussions can be provided based on examples where the anode AND is a pixel electrode layer, and the cathode CAT is a common electrode. But embodiments of the present disclosure are not limited thereto.

Each light emitting element ED can be configured by respective portions of a corresponding anode AND, a corresponding portion of the light emitting element intermediate layer EL, and a corresponding portion of the cathode CAT that overlap with each other. A corresponding light emitting area can be formed by each light emitting element ED. For example, a corresponding light emitting area of each light emitting element ED can include an area in which a corresponding anode AND, a corresponding portion of the light emitting element intermediate layer EL, and a corresponding portion of the cathode CAT overlap with each other. But embodiments of the present disclosure are not limited thereto.

In some aspects, the light emitting element ED can be an organic light emitting diode (OLED), an inorganic material-based light emitting diode (LED), or a quantum dot light emitting element. For example, when the light emitting element ED is an organic light emitting diode OLED, the light emitting element intermediate layer EL of this light emitting element ED can be a light emitting element intermediate layer including an organic material.

The driving transistor DT can be a transistor configured to supply a driving current to the light emitting element ED. The driving transistor DT can be connected between a first common driving voltage line VDDL and the light emitting element ED.

The driving transistor DT can include a first node N1 electrically connected with the light emitting element ED, a second node N2 to which a data signal VDATA is applied, and a third node N3 to which a driving voltage VDD through a driving voltage line DVL (e.g., the first common driving voltage line VDDL) is applied. But embodiments of the present disclosure are not limited thereto.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, embodiments of the present disclosure are not limited thereto.

The scan transistor ST included in the subpixel circuit SPC illustrated in FIG. 2 can be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

In one or more aspects, the storage capacitor Cst, which can be present between the first node N1 and the second node N2 of the driving transistor DT, can be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like).

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In an example where the display panel 110 has the bottom emission structure, the subpixel circuit SPC may not overlap the light emitting element ED in the vertical direction.

As shown in FIG. 2, the subpixel circuit SPC can include two transistors (2T: DT and ST) and one capacitor (1C: Cst) (which can be referred to as a “2T1C structure”), and in some implementations, can further include one or more transistors, or further include one or more capacitors. But embodiments of the present disclosure are not limited thereto.

For example, the subpixel circuit SPC can have an 8T1C structure including 8 transistors and 1 capacitor. In another example, the subpixel circuit SPC can have an 6T2C structure including 6 transistors and 2 capacitor. In further another example, the subpixel circuit SPC can have an 7T1C structure including 7 transistors and 1 capacitor.

The types and number of gate signals supplied to a subpixel SP, and/or the types and number of gate lines connected to the subpixel SP can vary depending on a structure of a corresponding subpixel circuit SPC.

Further, the types and number of common pixel driving voltages supplied to a subpixel SP can vary depending on a structure of a corresponding subpixel circuit SPC.

Since circuit elements (e.g., a light emitting element ED such as an organic light emitting diode (OLED) including an organic material) in each subpixel SP are vulnerable to external moisture or oxygen, an encapsulation layer 200 can be disposed in the display panel 110 in order to prevent the external moisture or oxygen from penetrating into the circuit elements (e.g., the light emitting element ED). The encapsulation layer 200 can be disposed in various shapes or configurations to prevent light emitting elements ED from contacting moisture or oxygen. But embodiments of the present disclosure are not limited thereto.

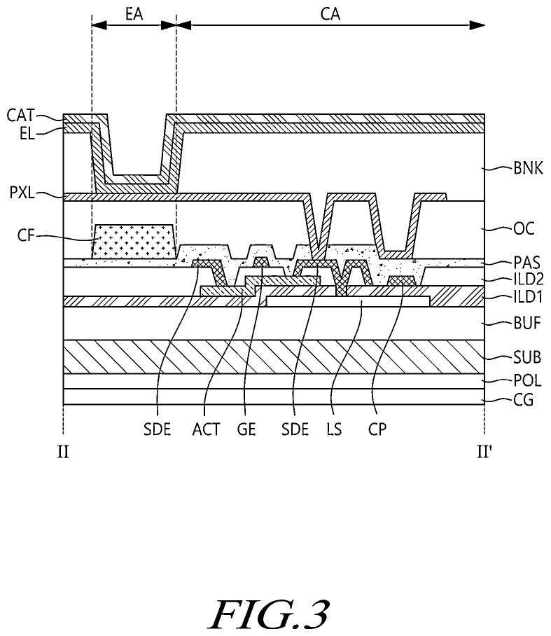

FIG. 3 is a cross-sectional view of a portion of an example display panel.

A substrate SUB can be a layer on which components of the display panel 110 are disposed. Different layers can be disposed on the top and bottom of the substrate SUB. Referring to FIG. 3, a buffer layer BUF can be disposed on the substrate SUB. A polarizer POL can be disposed under the substrate SUB.

The buffer layer BUF can be disposed on the substrate SUB.

A light shielding layer LS can be disposed on a portion of the buffer layer BUF. The light shielding layer LS can shield external light and prevent the characteristics of components disposed inside of the display panel 110 from changing due to external light. The light shielding layer LS can include, for example, a metal material, and can transfer an electrical signal. But embodiments of the present disclosure are not limited thereto.

A first interlayer dielectric layer ILD1 can be configured to cover the light shielding layer LS. A contact hole can be formed in a portion of the first interlayer dielectric layer ILD1.

An active layer ACT can be disposed on the first interlayer dielectric layer ILD1.

A second interlayer dielectric layer ILD2 can be configured to cover the active layer ACT and the first interlayer dielectric layer ILD1.

Electrodes (SDE and GE) of a driving transistor can be disposed on the second interlayer dielectric layer ILD2. A contact hole can be formed in a portion of the second interlayer dielectric layer ILD2. The electrodes (SDE and GE) of the driving transistor can include a gate electrode GE and two source-drain electrodes SDE. One of the two source-drain electrodes SDE can be electrically connected to the light shielding layer LS.

A capacitor electrode pattern CP can be disposed on the first interlayer dielectric layer ILD1.

A passivation layer PAS can be configured to cover the electrodes (SDE and GE) of the driving transistor and the second interlayer dielectric layer ILD2.

A color filter CF can be disposed on the passivation layer PAS.

An overcoat layer OC can be configured to cover the color filter CF and the passivation layer PAS.

A pixel electrode layer PXL can be disposed on the overcoat layer OC. The pixel electrode layer PXL can be electrically connected to the source or drain electrode SDE through contact holes formed in the passivation layer PAS and the overcoat layer OC.

A bank layer BNK can be disposed on the pixel electrode layer PXL and the overcoat layer OC.

An emission layer EML of a light emitting element intermediate layer EL can be disposed on the bank layer BNK. The emission layer EML can be electrically connected to the pixel electrode layer PXL through a contact hole formed in the bank layer BNK.

A cathode CAT can be disposed on the emission layer EML.

The polarizer POL can be disposed under the substrate SUB.

A cover glass CG can be disposed under the polarizer POL. The cover glass CG can include an anti-glare (AG) layer, a semi-glare (SG) layer, a low-reflection (LR) layer, and an anti-glare and low-reflection (AGLR) layer.

In an example where a polarizer POL is not included in the display device 100, external light can be reflected by the display panel 110 and reach a user in front thereof. In this situation, visibility of the image can be reduced. In an example where a polarizer POL is included in the display device 100, external light may not be reflected to a user.

However, as the polarizer POL is disposed, the polarizer can present a number of disadvantages. When a polarizer POL is included in a display device, light transmittance can be lowered. Thereby, the power consumption of the display device can increase. Further, since a polarizer POL has a great thickness, the polarizer can be disadvantageous to be applied to flexible display devices. The application of the polarizer to display devices can increase substantial manufacturing costs.

To address these issues, one or more example embodiments of the present disclosure can provide a display device capable of reducing the reflection of light.

One or more example embodiments of the present disclosure can provide a display device capable of reducing the reflection of light and ensuring visibility of a repair area.

One or more example embodiments of the present disclosure can provide a display device capable of being driven at low power as the reflection of light is reduced. Example embodiments of the present disclosure will be discussed in detail below.

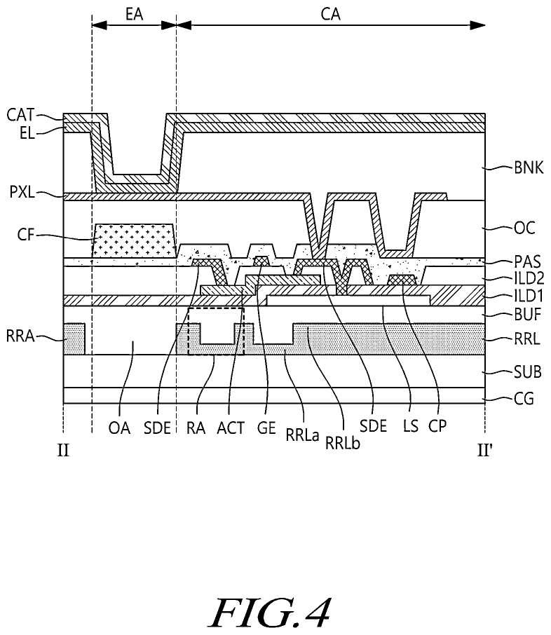

FIG. 4 is a cross-sectional view of an example portion of the display panel 110 according to aspects of the present disclosure.

Referring to FIG. 4, in one or more example embodiments, a reflection reduction layer RRL can be disposed between a substrate SUB and a buffer layer BUF.

The reflection reduction layer RRL can be a layer capable of preventing external light from being reflected to a user.

The reflection reduction layer RRL can include an open area OA and a reflection prevention area RRA.

The open area OA can correspond to a light emitting area EA. After the reflection reduction layer RRL is deposited on the entire surface of the substrate SUB within a predefined area, a portion of the reflection reduction layer RRL corresponding to the light emitting area EA can be removed so that the open area OA of the reflection reduction layer RRL can be an area corresponding to the light emitting area EA. The display device 100 can further include a color filter CF located between an emission layer EML and the substrate SUB and configured to correspond to the open area OA. In various embodiments of the present disclosure, the color filter CF can correspond to the light emitting area EA, and the color filter CF, the open area OA and the light emitting area EA can be aligned in a light incident direction. In this regard, a width of the color filter CF can match a width of at least one of the open area OA and the light emitting area EA, but embodiments of the present disclosure are not limited thereto. For example, widths of one or more of the color filter CF, the open area OA and the light emitting area EA can be different from one another.

The reflection prevention area RRA can be an area outside of the open area OA. The reflection prevention area RRA can be an area except for the open area OA. External light may not reach a user due to the reflection prevention area RRA.

The reflection reduction layer RRL can include a black property. For example, the reflection reduction layer RRL can include a material that does not reflect external light. The main function of the reflection reduction layer RRL is to prevent or reduce the reflection of external light, and in one or more aspects, the reflection reduction layer RRL can be configured with a mixture of red and blue properties, but embodiments of the present disclosure are not limited thereto, and other color properties or a combination of color properties are possible.

The reflection reduction layer RRL can be formed at a high temperature in the process of forming a light shielding layer LS, first and second interlayer dielectric layers (ILD1 and ILD2), and an active layer ACT located on the reflection reduction layer RRL. For example, the reflection reduction layer RRL can have high heat resistance properties so that the reflection reduction layer RRL can be not deformed while those layers located on the reflection reduction layer RRL are formed.

In an example where the reflection reduction layer RRL has high heat resistance characteristics, the reflection reduction layer RRL can be not deformed even at a temperature of about 350 degrees. Since the reflection reduction layer is desired not to be deformed at high temperatures, for example, the reflection reduction layer RRL with high heat resistance characteristics can include carbon black. But embodiments of the present disclosure are not limited thereto.

The function of the reflection reduction layer RRL can be evaluated by optical density. The relatively higher the optical density, the better the light shielding function, and the relatively lower the optical density, the worse the light shielding function.

Since the reflection reduction layer RRL is disposed between the substrate SUB and the buffer layer BUF, external light may not reach a user. Thus, even if the display panel 110 does not have a polarizer, visibility deterioration due to external light can be prevented or reduced.

In one or more aspects, the display panel 110 can include a plurality of repair areas RA. The repair area RA can be formed in a circuit area CA.

The reflection reduction layer RRL can include a second part RRLb that is an outer area of the repair area RA, and a first part RRLa that corresponds to a repair area RA and is thinner than the second part RRLb.

The thickness of the first part RRLa can be relatively thinner than the thickness of the second part RRLb. In a case where the thickness of the reflection reduction layer RRL corresponding to the repair area RA is thick, the repair area RA may not be visible from outside of the display device 100. Since the thickness of the first part RRLa can be relatively thinner than the thickness of the second part RRLb, the repair area RA can be visible from outside of the display device 100.

Thus, as the repair area RA can be visible from outside of the display device 100, the optical density of the reflection reduction layer RRL corresponding to the repair area RA can be 0.1 to 0.6. When the optical density of the reflection reduction layer RRL corresponding to the repair area RA is 0.6 or more, a whitening defect can occur in the reflection reduction layer RRL due to damage caused by a laser, and the like during a circuit repair process. For example, when the optical density of the reflection reduction layer RRL corresponding to the repair area RA is 0.1 to 0.6, such a whitening defect that can be caused in the reflection reduction layer RRL can be prevented or reduced. But embodiments of the present disclosure are not limited thereto.

In various embodiments of the present disclosure, a base optical density of the reflection reduction layer RRL can be the same throughout the reflection reduction layer RRL so that a same thickness of one part of the reflection reduction layer RRL and another part of the reflection reduction layer RRL provides the same optical density value. But embodiments of the present disclosure are not limited thereto. For example, different parts of the reflection reduction layer RRL can be provided to have a different base optical density so one part of the reflection reduction layer RRL and another part of the reflection reduction layer RRL can have different optical density values even when the one part and the another part of the reflection reduction layer RRL have the same thickness.

Further, the whitening defect can be prevented or reduced depending on a thickness of the reflection reduction layer RRL corresponding to the repair area RA, and the whitening defect can be prevented or reduced depending on a transmittance of the reflection reduction layer RRL. Discussions on a thickness of the reflection reduction layer RRL and a transmittance of the reflection reduction layer RRL corresponding to the repair area RA will be further provided after discussions on the buffer layer BUF are provided.

In various embodiments of the present disclosure, the reflection reduction layer RRL can have various thicknesses whereby the first part RRLa can have a first thickness, the second part RRLb can have a second thickness different from the first thickness, and the open area OA can have no thickness, but embodiments of the present disclosure are not limited thereto. For example, the thickness of the second part RRLb need not be constant, and can vary within a range of 20% or less. Also, the thickness of the first part RRLa need not be constant, and can vary within a range of 20% or less. Additionally, a plurality of first parts RRLa can be provided, whereby the plurality of first parts RRLa can have the same thickness or different thicknesses. When the plurality of first parts RRLa are provided, the plurality of first parts RRLa can be separated from each other by a portion of the second part RRLb, or can be connected to each other. When the plurality of first parts RRLa of different thicknesses are connected to each other, one or more step sections can be present where the plurality of first parts RRLa are connected to each other. In various embodiments of the present invention, the second thickness of the second part RRLb can be a maximum thickness of the reflection reduction layer RRL.

In various embodiments of the present disclosure, the buffer layer BUF can have different thicknesses. Although the thicknesses of the buffer layer BUF vary based on contact points between the buffer layer BUF and the reflection reduction layer RRL, but embodiments of the present disclosure are not limited thereto. For example, combined thicknesses of the buffer layer BUF and the reflection reduction layer RRL can be the same or constant, but in other embodiments of the present disclosure, a first combined section of the buffer layer BUF and the reflection reduction layer RRL can have a different thickness from a second combined section of the buffer layer BUF and the reflection reduction layer RRL. When different one or more of another layer can be interposed between the buffer layer BUF and the reflection reduction layer RRL, such as an adhesive layer, or a polarizer.

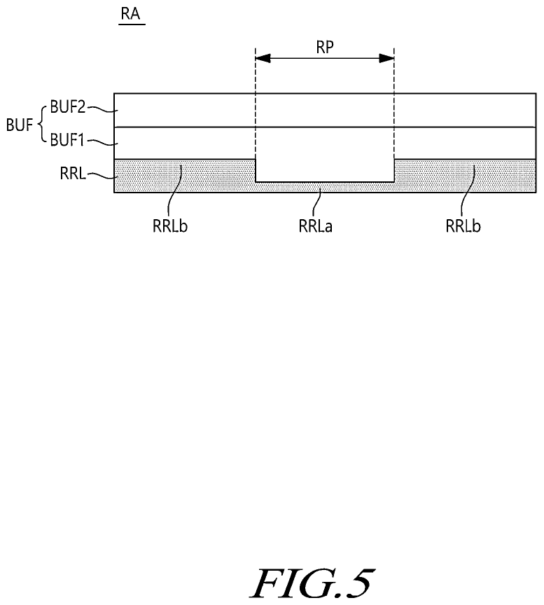

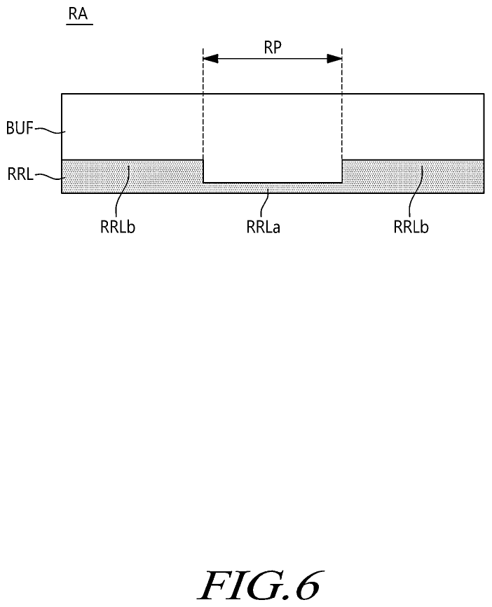

FIG. 4 illustrates the repair area RA. Discussions on a repair area RA are provided in more detail with reference to FIGS. 5 and 6.

FIGS. 5 and 6 are cross-sectional views of an example repair area in the display panel 110 according to aspects of the present disclosure.

Referring to FIG. 5, in one or more example embodiments, a buffer layer BUF can be disposed on a reflection reduction layer RRL.

The buffer layer BUF can include a first buffer layer BUF1 including a transparent material and configured to have a flat surface, and a second buffer layer BUF2 disposed on the first buffer layer BUF1.

As the firsts buffer layer BUF1 can include a transparent materials and can have a flat top surface, the first buffer layer BUF1 can be referred to as a transparent planarization layer.

The second buffer layer BUF2 can be disposed on the first buffer layer BUF1.

The second buffer layer BUF2 can be configured to have a flat surface on the first buffer layer BUF1.

Referring to FIG. 5, a first part RRLa of the reflection reduction layer RRL can correspond to the location of a repair pattern RP.

Referring to FIG. 6, the buffer layer BUF can be disposed on the reflection reduction layer RRL. In various embodiments of the present disclosure, the buffer layer BUF can be a single layer.

The buffer layer BUF can include at least one of silicon dioxide (SiO₂) or silicon nitride (SiNx). For example, the buffer layer BUF can include an insulating-capable material. But embodiments of the present disclosure are not limited thereto.

The thickness of the buffer layer BUF can be 0.5 micrometer or more. When the thickness of the buffer layer BUF is less than 0.5 micrometers, the characteristics of one or more elements or layers included in the display panel 110 can be unstable due to the non-uniformity (or the non-uniformity of the top and/or bottom surfaces) of the reflection reduction layer RRL. For example, when the thickness of the buffer layer BUF is 0.5 micrometer or more, the stability of the display panel 110 can be improved. Here, 0.5 micrometer is equal to 5000 angstroms. But embodiments of the present disclosure are not limited thereto.

The thickness of the reflection reduction layer RRL can be 0.1 micrometer to 0.5 micrometer, and the transmittance of the reflection reduction layer RRL corresponding to the repair area RA can be 50% or more. When the transmittance of the reflection reduction layer RRL is 50% or more, a whitening defect that can occur in the reflection reduction layer RRL during the repair process can be prevented or reduced.

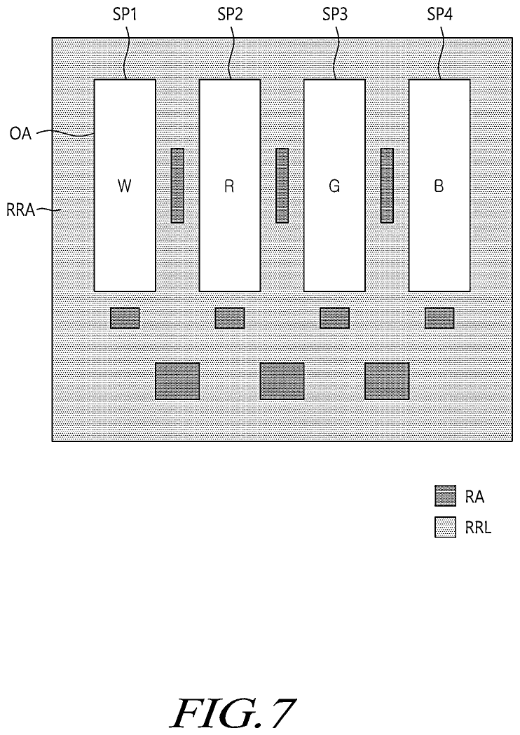

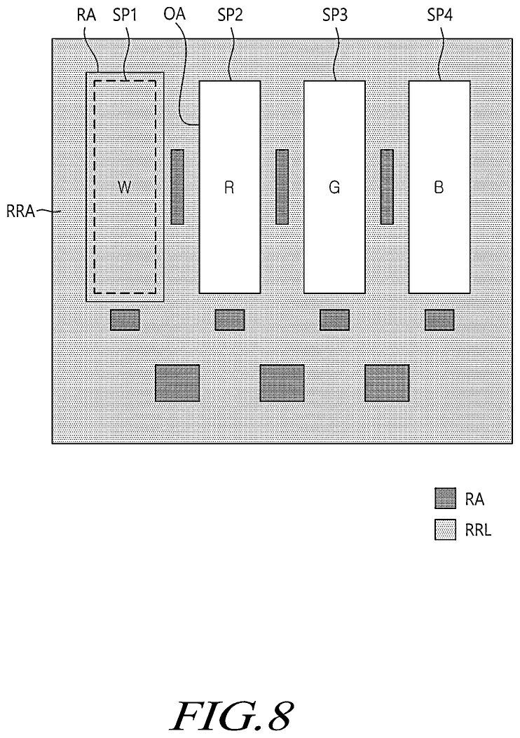

FIGS. 7 and 8 are plan views illustrating an example reflection reduction layer RRL included in the display panel 110 according to aspects of the present disclosure.

In one or more example embodiments, FIG. 7 illustrates at least one open area OA and a reflection prevention area RRA included in the reflection reduction layer RRL.

Each open area OA of the reflection reduction layer RRL can be a corresponding light emitting area EA.

Referring to FIG. 7, open areas OA of the reflection reduction layer RRL can be areas resulting from removing areas corresponding to the open areas OA after the reflection reduction layer RRL is deposited on the entire surface within a predefined area.

FIG. 7 illustrates a plurality of repair areas RA. A first portion RRLa of the reflection reduction layer RRL can correspond to the plurality of repair areas RA.

The reflection reduction layer RRL can prevent external light from being reflected to a user without affecting the brightness of light emitting areas EA.

One pixel can include a plurality of subpixels SP. For example, one pixel can include four subpixels SP1 through SP4 of W, R, G, and B, respectively. That is, in an example where one pixel includes four subpixels SP1 through SP4, the four subpixels SP can be red (R), green (G), blue (B), and white (W) subpixels SP. In this case, reflectance of a white light emitting area EA of the white subpixel SP can be severe. But embodiments of the present disclosure are not limited thereto. FIG. 8 illustrates an example where the great reflectance of such a white light emitting area EA can be solved.

FIG. 8 illustrates a first subpixel SP1, a second subpixel SP2, a third subpixel SP3, and a fourth subpixel SP4.

The reflection reduction layer RRL can be disposed in a light emitting area EA of the first subpixel SPL. The reflection reduction layer RRL may not be disposed in respective light emitting areas EA of the second subpixel SP2, third subpixel SP3, and fourth subpixel SP4.

The first subpixel SP1 can be a subpixel SP representing a white color.

The reflection reduction layer RRL corresponding to the light emitting area EA of the first subpixel SP1 can be configured with a first part RRLa of the reflection reduction layer RRL, and the optical density of the reflection reduction layer RRL corresponding to the light emitting area EA of the first subpixel SP1 can be 0.1 to 0.6. In particular, when the optical density of the first subpixel SP1 is 0.6, corresponding reflectance can be further reduced by 5%.

For example, as the reflection reduction layer is disposed in the opening area of the subpixel representing the white color, the reflectance of the opening area of the subpixel representing the white color can be reduced. But embodiments of the present disclosure are not limited thereto.

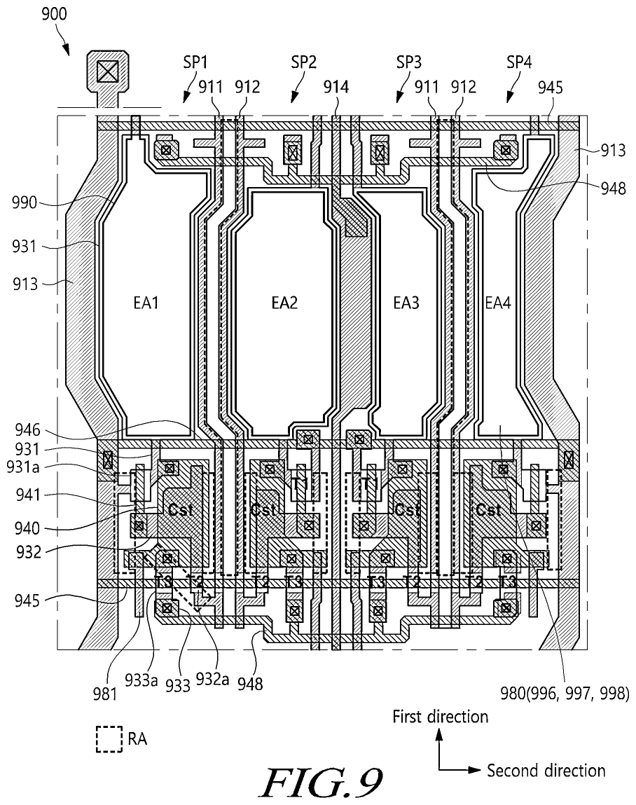

FIG. 9 is a plan view illustrating an example portion of the display panel 110 in which subpixels and repair areas are disposed according to aspects of the present disclosure.

Referring to FIG. 9, in one or more example embodiments, the display device 100 can include an active area in which a plurality of subpixels are disposed and a non-active area in which a plurality of pad electrodes are disposed.

Referring to FIG. 9, a plurality of lines and a plurality of electrodes can be disposed on a substrate 900. A reflection reduction layer can be disposed on the substrate 900. A buffer layer can be disposed on the reflection reduction layer.

Referring to FIG. 9, a plurality of subpixels SP can include first to fourth subpixels (SP1, SP2, SP3, and SP4).

Referring to FIG. 9, the first subpixel SP1 can be a subpixel including a first light emitting area EA1 emitting a red light, the second subpixel SP2 can be a second light emitting area EA2 emitting a white light, the third subpixel SP3 can be a subpixel including a third light emitting area EA3 emitting a blue light, and the fourth subpixel SP4 can be a subpixel including a fourth light emitting area EA4 emitting a green light. But embodiments of the present disclosure are not limited thereto, and other colors and/or different order of colors can be emitted from the first through fourth light emitting areas EA1 to EA4. Different number of light emitting areas EA or subpixels SP are within the scope of the present disclosure, so that number of the light emitting areas EA or the subpixels SP can be greater than 4 or less than 4.

Referring to FIG. 9, the subpixels (SP1, SP2, SP3, and SP4) can have respective light emitting areas (EA1, EA2, EA3, and EA4) defined by a bank layer 990 and a non-light emitting area that is an area other than the light emitting areas.

The first to fourth light emitting areas (EA1, EA2, EA3, and EA4) can be not overlapping with the bank layer 990, and at least a portion of the non-light emitting area can overlap with the bank layer 990. An organic light emitting element, such as an organic light emitting diode 980, and the like, including a first electrode 996, an organic layer 997, and a second electrode 998 can be disposed in each light emitting area EA.

Circuit areas for driving the organic light emitting elements can be disposed in a non-light emitting area. A plurality of signal lines, a plurality of transistors, and at least one storage capacitor Cst can be disposed in each circuit area. Referring to FIG. 9, a first signal line 911, a second signal line 912, a third signal line 913, and a fourth signal line 914 can be disposed on the substrate 900.

Each of the plurality of subpixels (SP1, SP2, SP3, and SP4) can include first to third active layers (931, 932, and 933).

Referring to FIG. 9, the second active layer 932 and the third active layer 933 can be disposed on the substrate 900 and disposed to be spaced apart from the first active layer 931.

Each of the first to third active layers (931, 932, and 933) can include channel regions (931a, 932a, and 933a), respectively. For example, the first active layer 931 can include a first channel region 931a, the second active layer 932 can include a second channel region 932a, and the third active layer 933 can include a third channel region 933a.

The first channel region 931a can be a channel region of the first transistor T1, the second channel region 932a can be a channel region of the second transistor T2, and the third channel region 933a can be a channel region of the third transistor T3.

Areas where the first to third active layers (931, 332, and 333) are connected to other components through contact holes can serve as source and drain electrodes of the first to third transistors (T1, T2, and T3), respectively.

As shown in FIGS. 9 and 4, the first active layer 931 in each subpixel (SP1, SP2, SP3, and SP4) can be disposed in the non-light emitting area and configured to extend to the light emitting areas (EA1, EA2, EA3, and EA4).

An area of the first active layer 931 disposed in the corresponding light emitting area (EA1, EA2, EA3, and EA4) of each subpixel (SP1, SP2, SP3, and SP4) and a corresponding portion of the non-light emitting area surrounding each light emitting area (EA1, EA2, EA3, and EA4) can serve as a first electrode (e.g., an anode electrode) of a corresponding organic light emitting element.

Referring to FIG. 9, the plurality of signal lines (911, 912, 913, and 914) can be disposed in the same layer as the first to third active layers (931, 932, and 933). The plurality of signal lines (911, 912, 913, and 914) can include the first signal line 911, the second signal line 912, the third signal line 913, and the fourth signal line 914. Each of the first to fourth signal lines (911, 912, 913, and 914) can be spaced apart from each other, and configured to extend in a first direction (e.g., the longitudinal direction or vertical direction). For example, the first and second signal lines (911 and 912) can be data lines, the third signal line 913 can be a driving voltage line, and the fourth signal line 914 can be a reference voltage line, but example embodiments of the present disclosure are not limited thereto.

Referring to FIG. 9, the first active layer 931 disposed in the first subpixel SP1 can be integrally formed with the third signal line 913, and the second active layer 932 can be integrally formed with the first signal line 911.

The second active layer 932 disposed in the second subpixel SP2 can be integrally formed with the second signal line 912.

The second active layer 932 disposed in the third subpixel SP3 can be integrally formed with the first signal line 911, and can be different from the first signal line 911 integrally formed with the second active layer 932 of the first subpixel SP1.

The first active layer 931 disposed in the fourth subpixel SP4 can be integrally formed with the third signal line 913, and can be different from the third signal line 913 integrally formed with the first active layer 931 of the first subpixel SP1.

The second active layer 932 disposed in the fourth subpixel SP4 can be integrally formed with the second signal line 912, and can be different from the second signal line 912 integrally formed with the second active layer 932 of the second subpixel SP2.

A fifth signal line 945 can be a scan line extending in a second direction (e.g., the horizontal direction) intersecting the first direction.

As shown in FIG. 9, a portion of the fifth signal line 945 can overlap respective portions of the second active layer 932 and the third active layer 933.

The fifth signal line 945 can serve as respective gate electrodes of the second transistor T2 and the third transistor T3.

Respective areas where the second and third active layers (932 and 333) overlaps with the fifth signal line 945 and a second insulating layer 902 can be channel regions of the second active layer 932 and the third active layer 933, respectively.

A first extension 946 can be electrically connected to the third signal line 913. The plurality of subpixels (SP1, SP2, SP3, and SP4) can receive a driving voltage through the first extension 946.

A second extension 948 can be electrically connected to the fourth signal line 914. The plurality of subpixels (SP1, SP2, SP3, and SP4) can receive a reference voltage through the second extension 948.

As shown in FIG. 9, a portion of a plate 940 in each subpixel (SP1, SP2, SP3, and SP4) can overlap with a portion of each of the first to third active layers (931, 932, and 933).

The first active layer 931 can contact, and be electrically connected to, the plate 940 through a contact hole.

The third active layer 933 also contact, and be electrically connected to, the plate 940 through a contact hole.

As shown in FIGS. 9 and 4, the second active layer 932 can overlap with the plate 940, and thus, form a storage capacitor Cst. For example, the second active layer 932 and the plate 940 can serve as electrodes of the storage capacitor Cst.

A portion of a first electrode pattern 941 can overlap with a portion of the first active layer 931.

The first electrode pattern 941 can serve as a gate electrode of the first active layer 931. But embodiments of the present disclosure are not limited thereto.

As shown in FIGS. 9 and 4, an area where the first active layer 931 overlaps with the first electrode pattern 941 and the second insulating layer 902 can be the channel region 931a of the first active layer 931.

As shown in FIG. 9, the first electrode pattern 941 can contact, and be electrically connected to, the second active layer 932 through a contact hole.

FIG. 9 illustrates a plurality of repair areas RA. Each repair area RA can include a repair pattern. Each repair area RA can overlap with an area where a plurality of signal lines are disposed. Each repair area RA can overlap with an area where at least one transistor is disposed.

For example, each of the plurality of subpixels (SP1, SP2, SP3, and SP4) can include a repair pattern 981 disposed between one of the first to fourth signal lines ((911, 912, 913, and 914) and the third active layer 933. The repair pattern 981 can be included in the repair area RA. But embodiments of the present disclosure are not limited thereto.

When a subpixel defect such as bright spots or dark spots occurs, an electrical connection between the first active layer 931 extending to the light emitting area and a circuit area can be disconnected using a laser or the like.

Thereafter, the repair pattern 981 can be electrically connected to the plate 940 through a welding process. For example, the repair pattern 981 and the plate 940 disposed on the repair pattern 981 can contact each other. But embodiments of the present disclosure are not limited thereto.

Referring to FIG. 9, the repair pattern 981 can be electrically connected to a circuit area of another adjacent subpixel, and the defective subpixel can be driven through the adjacent circuit area electrically connected to the repair pattern 981.

In this manner, the first to third active layers (931, 932, and 933), the first to fourth signal lines (911, 912, 913, and 914), and the repair pattern 981 can be disposed in the same layer and formed through the same process. Thereby, the process of manufacturing an organic light emitting display device (i.e., the display device 100) can be simplified.

A reflection reduction layer RLL can be disposed on the substrate 900. A buffer layer BUF can be disposed on the reflection reduction layer RRL. As the reflection reduction layer RRL is disposed on the substrate 900, corresponding reflectance can be reduced. In addition, the thickness of the reflection reduction layer RRL can be relatively thin in the repair area RA, and therefore, visibility of the repair area RA can be ensured.

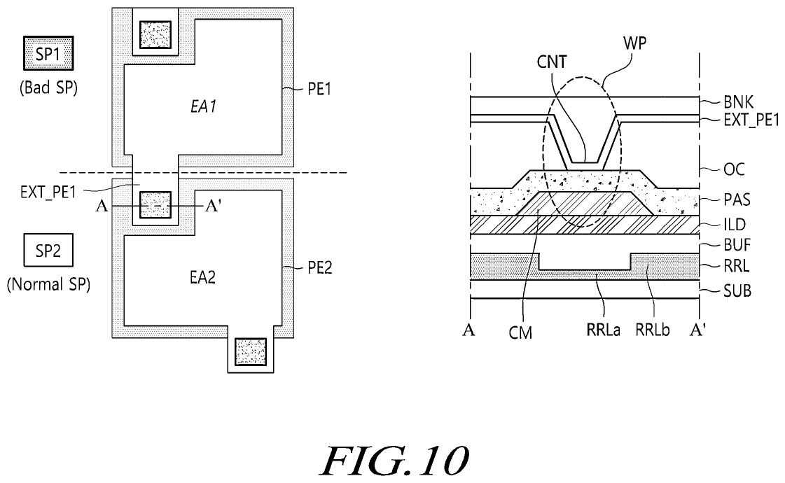

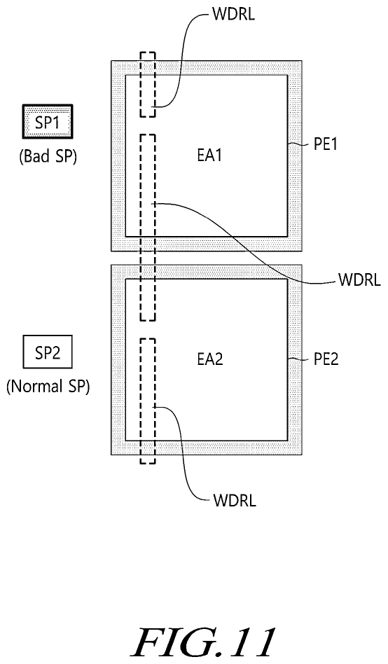

FIGS. 10 and 11 illustrate an example repair structure according to aspects of the present disclosure. For discussions, it is assumed that in FIGS. 10 and 11, a first subpixel SP1 is a bad subpixel (Bad SP) and a second subpixel SP2 is a normal subpixel (Normal SP).

Referring to FIGS. 10 and 11, in one or more example embodiments, the first subpixel SP1 can include a first pixel electrode PE1 for forming a corresponding light emitting element ED, and the second subpixel SP2 can include a second pixel electrode PE2 for forming a corresponding light emitting element ED. The first subpixel SP1 can have a first light emitting area EA1 whose area corresponds to the first pixel electrode PE1, and the second subpixel SP2 can have a second light emitting area EA2 whose area corresponds to the second pixel electrode PE2.

In one or more aspects, repair can be performed by one or more of an upper repair scheme (FIG. 10) performed on the substrate SUB on which the pixel electrodes PE are patterned, and a lower repair scheme (FIG. 11) performed under the substrate SUB.

Referring to FIG. 10, in the case of the upper repair scheme, welding repair can be performed for the pixel electrodes PE1 and PE2. To allow such repair to be performed, the first pixel electrode PE1 of the first subpixel SP1 can include an extension portion EXT_PE1 extending to an area of the second subpixel SP2.

A connection metal CM can be disposed under the extended portion EXT_PE1 of the first pixel electrode PE1. A passivation layer PAS and an overcoat layer OC can be disposed between the extended portion EXT_PE1 of the first pixel electrode PE1 and the connecting metal CM.

The extended portion EXT_PE1 of the first pixel electrode PE1 can include a contact portion CNT contacting the top surface of the passivation layer PAS through a hole of the overcoat layer OC.

The contact portion CNT of the extended portion EXT_PE1 of the first pixel electrode PE1 can be located at a welding point WP where welding repair is performed at a welding repair layer WDRL.

Before the welding repair is performed, the contact portion CNT of the extended portion EXT_PE1 of the first pixel electrode PE1 can be electrically separated from the connection metal CM.

After the welding repair is performed, the extended portion EXT_PE1 of the first pixel electrode PE1 can be electrically connected to the connection metal CM at the contact portion CNT.

The connection metal CM can be a portion of a subpixel circuit SPC of the second subpixel SP2 or can be a metal electrically connected to the subpixel circuit SPC of the second subpixel SP2.

For example, the connection metal CM can be a second node N2 or a second pixel electrode PE2 of a driving transistor DRT of the second subpixel SP2. In another example, the connection metal CM can be electrically connected to the second node N2 of the driving transistor DRT of the second subpixel SP2 or can be electrically connected to the second pixel electrode PE2. But embodiments of the present disclosure are not limited thereto.

Accordingly, after the welding repair is performed, when the contact portion CNT of the extended portion EXT_PE1 of the first pixel electrode PE1 is electrically connected to the connection metal CM, the first pixel electrode PE1 of the first subpixel SP1 can receive a driving current from the driving transistor DRT of the second subpixel SP2.

A reflection reduction layer RRL can be disposed on a substrate SUB.

A buffer layer BUF can be disposed on the reflection reduction layer RRL. An interlayer dielectric layer ILD can be on the Buffer layer BUF.

The buffer layer BUF can further include a first buffer layer BUF1 including a transparent material and configured to have a flat surface, and a second buffer layer BUF2 disposed on the first buffer layer BUF1.

The reflection reduction layer RRL can be disposed on the substrate SUB. The buffer layer BUF can be disposed on the reflection reduction layer RRL. As the reflection reduction layer RRL is disposed on the substrate SUB, corresponding reflectance can be reduced. In addition, the thickness of the reflection reduction layer RRL can be relatively thin in the repair area RA, and therefore, visibility of the repair area RA can be ensured.

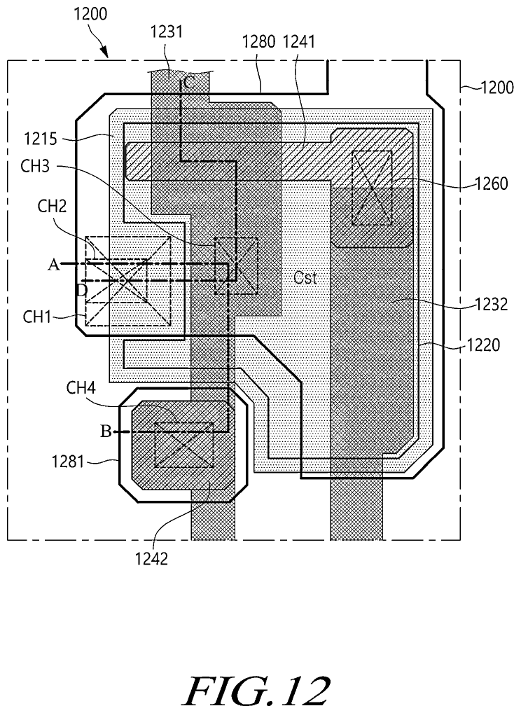

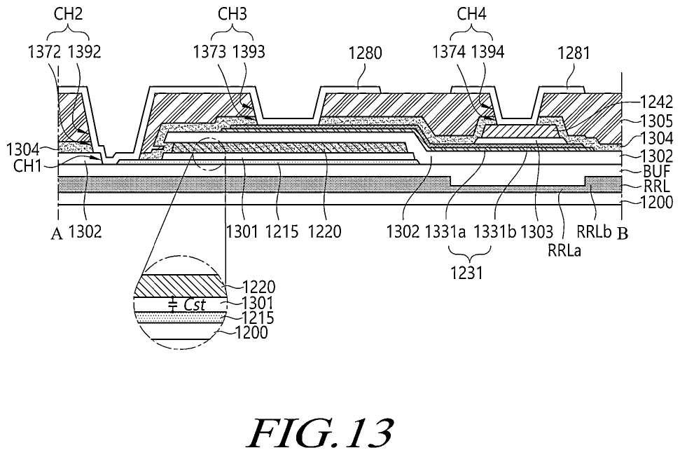

FIG. 12 is an example plan view illustrating a portion of a circuit area of a subpixel disposed in an active area of the display device 100 according to aspects of the present disclosure. FIG. 13 is an example cross-sectional view taken along with line A-B of FIG. 12.

Referring to FIG. 12, in one or more example embodiments, a display device can include a light emitting area and a non-light emitting area disposed in the active area AA.

Referring to FIG. 12, a first conductive layer 1215 can be disposed on a substrate 1200.

A plurality of signal lines can be disposed in the same layer as the first conductive layer 1215. For example, at least one data line, at least one reference voltage line, and at least one driving voltage line can be disposed.

A second conductive layer 1220 can be disposed over the substrate 1200 on which the first conductive layer 1215 is disposed.

The first conductive layer 1215 and the second conductive layer 1220 can overlap with each other and serve as electrodes of a storage capacitor Cst.

Further, the first and second conductive layers (1215 and 1220) can perform the function of absorbing light incident from the substrate 1200 and preventing the light from reaching at least one active layer disposed on the first and second conductive layers 1215 and 1220.

A plurality of active layers (1231 and 1232) can be disposed over the substrate 1200 over which the second conductive layer 1220 is disposed.

For example, one subpixel can include a first active layer 1231 and a second active layer 1232. But embodiments of the present disclosure are not limited thereto.

Each of the first and second active layers (1231 and 1232) can be configured with a stack of double layers. For example, each of the first and second active layers (1231 and 1232) can include a first active pattern and a second active pattern disposed on the first active pattern.

The first active pattern of each of the first and second active layers (1231 and 1232) can be a conductivity-enabled region resulting from performing conductivity-enabling process for the remaining region except for a channel region to act as a conductor.

The first active pattern of each of the first and second active layers (1231 and 1232) can include an oxide semiconductor. The second active pattern of each of the first and second active layers 1231 and 1232 can be a metal layer.

A portion of each of the first and second active layers (1231 and 1232) can overlap with respective portions of the first and second conductive layers (1215 and 1220).

Although FIG. 12 illustrates only an area where the first and second active layers (1231 and 1232) are disposed on the substrate 1200, but the structure of the display device 100 according to example embodiments of the present disclosure is not limited thereto. For example, one or more active layers can be additionally disposed in the circuit area of one subpixel. But embodiments of the present disclosure are not limited thereto.

An area where the first active pattern of the first and second active layers (1231 and 1232) overlaps with the second active pattern can be a non-conductivity-enabled region, and an area where the first active pattern does not overlap with the second active pattern can be a conductivity-enabled region.

A first electrode pattern 1241 and a second electrode pattern 1242 can be disposed over the substrate 1200 over which the first and second active layers (1231 and 1232) are disposed.

Referring to FIG. 12, the first electrode pattern 1241 can be disposed in the same layer as a scan line.

The first electrode pattern 1241 can overlap with a portion of each of the first and second active layers 1231 and 1232.

One or more portions of the first active layer 1231 can be conductivity-enabled regions and serve as source and drain electrodes of a corresponding driving transistor.

Referring to FIG. 12, a portion of the first active layer 1231 can be electrically connected to a driving voltage line, and another portion of the first active layer 1231 can be electrically connected to another electrode pattern disposed in the same layer as the first electrode pattern 1241.

A portion of the first electrode pattern 1241 overlapping with the first active layer 1231 can be a channel region of the driving transistor.

The first electrode pattern 1241 can serve as a gate electrode of the driving transistor.

As shown in FIG. 12, a storage capacitor Cst can be disposed under the driving transistor, and the driving transistor can overlap with the storage capacitor Cst.

A portion of the first electrode pattern 1241 can be electrically connected to the second active layer 1232 through a contact hole 1260.

The second active layer 1232 can be included in a scan transistor.

One or more portions of the second active layer 1232 can be conductivity-enabled regions and serve as source and drain electrodes of the scan transistor.

Referring to FIG. 12, a portion of the second active layer 1232 overlapping with the gate electrode of the scan transistor can be a channel region of the scan transistor.

Further, another portion of the second active layer 1232 of the scan transistor can be electrically connected to a signal line (e.g., a data line).

Referring to FIG. 12, a first electrode 1280 of an organic light emitting element such an organic light emitting diode (OLED) can be configured to overlap with a light emitting area and a portion of a circuit area, which is a non-light emitting area surrounding the light emitting area.

The first electrode 1280 can be an anode electrode or a cathode electrode of the organic light emitting diode (OLED).

The first electrode 1280 can contact the first conductive layer 1215 through a first contact hole CH1 and a second contact hole CH2.

The first contact hole CH1 and the second contact hole CH2 can be contact holes formed in one or more insulating layers disposed on the first conductive layer 1215.

In this implementation, a portion of the first contact hole CH1 and the entire second contact hole CH2 can overlap with each other.

For example, an area of the first contact hole CH1 can be greater than that of the second contact hole CH2 in a plane view.

As shown in FIG. 12, each of the first contact hole CH1 and the second contact hole CH2 can overlap with a portion of one side of the first conductive layer 1215.

Each of the first contact hole CH1 and the second contact hole CH2 can be spaced apart from the second conductive layer 1220.

For example, the first contact hole CH1 and the second contact hole CH2 can overlap with the portion of one side of the first conductive layer 1215, and can be disposed in an area where the first conductive layer 1215 does not overlap with the second conductive layer 1220. But embodiments of the present disclosure are not limited thereto.

The first electrode 1280 can contact a portion of the top surface and a portion of the side surface of the first conductive layer 1215 through the first and second contact holes (CH1 and CH2), which overlap with the first electrode 1280.

According to this implementation, the first electrode 1280 can be electrically connected to a portion of the top surface of the first active layer 1231.

For example, the first electrode 1280 can contact a portion of the top surface of the first active layer 1231 through a third contact hole CH3.

Accordingly, the first conductive layer 1215 can be provided with potential applied to the first active layer 1231. But embodiments of the present disclosure are not limited thereto.

As shown in FIG. 12, a repair pattern 1281 disposed in the same layer as the first electrode 1280 can be disposed in the circuit area.

When a subpixel defect such as bright spots or dark spots occurs, a connection between the first electrode 1280 and the circuit area can be disconnected using a laser or the like.

Afterwards, the second electrode pattern 1242 can be electrically connected to the first active layer 1231 disposed below the second electrode pattern 1242 through a welding process.

The second electrode pattern 1242 can be disposed in the same layer as the first electrode pattern 1241.

For example, the repair pattern 1281 can contact a portion of the top surface of the second electrode pattern 1242 through a fourth contact hole CH4.

The second electrode pattern 1242 can contact the first active layer 1231 disposed under the second electrode pattern 1242.

Referring to FIG. 12, the repair pattern 1281 can be electrically connected to a circuit area of another adjacent subpixel, and the defective subpixel can be driven through the adjacent circuit area electrically connected to the repair pattern 1281.

In discussions that follow, some configurations, effects, and the like of the example embodiments or examples discussed above may not be repeatedly described for convenience of description. It should be, however, understood that the scope of the present disclosure includes such omitted configurations already discussed above. Further, elements or configurations the same or substantially the same as, or corresponding to, the example embodiments or examples described above are described using the same reference numerals.

Referring to FIG. 13, the first conductive layer 1215 can be disposed on the substrate 1200.

A first insulating layer 1301 can be disposed on the first conductive layer 1215.

The first insulating layer 1301 can be disposed on the first conductive layer 1215 and configured to expose a portion of the top surface and a portion of at least one side surface of the first conductive layer 1215. Further, the first insulating layer 1301 can be configured to expose a portion of the top surface of the substrate 1200.

The second conductive layer 1220 can be disposed on the first insulating layer 1301.

The second conductive layer 1220 can overlap with a portion of the first conductive layer 1215.

The second conductive layer 1220 may not be disposed in an area corresponding to an area where the first insulating layer 1301 exposes the portion of the top surface and the portion of the at least one side surface of the first conductive layer 1215.

As shown in FIG. 13, the first conductive layer 1215 and the second conductive layer 1220 that overlap with each other can serve as electrodes of a storage capacitor Cst.

A second insulating layer 1302 can be disposed over the substrate 1200 over which the second conductive layer 1220 is disposed.

As shown in FIG. 13, the second insulating layer 1302 can include the first contact hole CH1.

The first contact hole CH1 of the second insulating layer 1302 can overlap a portion of the top surface and a portion of a side surface of the first conductive layer 1215.

For example, the first contact hole CH1 of the second insulating layer 1302 can overlap with the portion of the top surface and the portion of the side surface of the first conductive layer 1215 that do not overlap with the first insulating layer 1301 and the second conductive layer 1220. But embodiments of the present disclosure are not limited thereto.

As shown in FIG. 13, the second insulating layer 1302 can also be disposed on a portion of the top surface of the substrate 1200 exposed by the first insulating layer 1301.

The first active layer 1231 can be disposed on the second insulating layer 1302.

The first active layer 1231 can include a first active pattern 1331a disposed on the second insulating layer 1302 and a second active pattern 1331b disposed on the first active pattern 1331a.

The area of the second active pattern 1331b can be smaller than the area of the first active pattern 1331a in a plan view.

The first active layer 1231 can be configured to expose a portion of the top surface of the second insulating layer 1302 and may not overlap with the first contact hole CH1 of the second insulating layer 1302.

A third insulating layer 1303 can be disposed over the substrate 1200 over which the first active layer 1231 is disposed.

The third insulating layer 1303 can be disposed only on a portion of the top surface of the first active layer 1231. The third insulating layer 1303 can be a gate insulating layer.

The second electrode pattern 1242 can be disposed on the third insulating layer 1303.

A fourth insulating layer 1304 can be disposed over the substrate 1200 over which the second electrode pattern 1242 is disposed.

As shown in FIG. 13, the fourth insulating layer 1304 can include a second contact hole 1372, a third contact hole 1373, and a fourth contact hole CH 4 1374.

The second contact hole 1372 of the fourth insulating layer 1304 can overlap with a portion of the first contact hole CH1 of the second insulating layer 1302.

For example, the second contact hole 1372 of the fourth insulating layer 1304 can overlap with a portion of the top surface of the first conductive layer 1215. But embodiments of the present disclosure are not limited thereto.

The second contact hole 1372 of the fourth insulating layer 1304 can overlap with the portion of the top surface and the portion of the side surface of the first conductive layer 1215 that do not overlap with the first insulating layer 1301 and the second conductive layer 1220.

Further, as shown in FIG. 13, the fourth insulating layer 1304 can be configured to surround a side surface of the first active layer 1231, a side surface of the second insulating layer 1302, and a side surface of the second conductive layer 1220, and a side surface of the first insulating layer 1301, which overlap with the first conductive layer 1215.

The third contact hole 1373 of the fourth insulating layer 1304 can overlap with a portion of the first active layer 1231, and expose a portion of the top surface of the first active layer 1231.

The third contact hole 1373 of the fourth insulating layer 1304 can also overlap with the first and second conductive layers (1215 and 1220).

The fourth contact hole 1374 of the fourth insulating layer 1304 can expose a portion of the top surface of the second electrode pattern 1242.

The fourth contact hole 1374 of the fourth insulating layer 1304 can overlap with the first active layer 1231 and may not overlap with the first and second conductive layers (1215 and 1220).

A fifth insulating layer 1305 can be disposed on the fourth insulating layer 1304. The fifth insulating layer 1305 can include an organic insulating material.

The fifth insulating layer 1305 can include a second contact hole 1392, a third contact hole 1393, and a fourth contact hole 1394 of the fifth insulating layer 1305.

The second contact hole 1392 of the fifth insulating layer 1305 can be configured to correspond to the second contact hole 1372 of the fourth insulating layer 1304. The third contact hole 1393 of the fifth insulating layer 1305 can be configured to correspond to the third contact hole 1373 of the fourth insulating layer 1304. The fourth contact hole 1394 of the fifth insulating layer 1305 can be configured to correspond to the fourth contact hole 1374 of the fourth insulating layer 1304.

Hereinafter, the second contact holes (1372 and 1392 of the fourth and fifth insulating layers (1304 and 1305) can be referred to as a second contact hole CH2, the third contact holes (1373 and 1393) of the fourth and fifth insulating layers (1304 and 1305) can be referred to as a third contact hole CH3, and the fourth contact holes (1374 and 1394) of the fourth and fifth insulating layers (1304 and 1305) can be referred to as a fourth contact hole CH4.

A first electrode 1280 of an organic light emitting element such as an organic light emitting diode (OLED) and a repair pattern 1281 can be disposed over the substrate 1200 over which the fifth insulating layer 1305 is disposed.

For example, referring to FIG. 13, the first electrode 1280 can be disposed on a portion of the top surface of the fifth insulating layer 1305 and can be disposed along the second contact hole CH2 and the third contact hole CH3. But embodiments of the present disclosure are not limited thereto.

The first electrode 1280 can contact a portion of the top surface and a portion of a side surface of the first conductive layer 1215 through the second contact hole CH2 and the first contact hole CH1 of the second insulating layer 1302.

The first electrode 1280 can contact a portion of the top surface of the first active layer 1231 through the third contact hole CH3. As shown in FIG. 13, the first electrode 1280 can overlap with a portion of the top surface of the second active layer pattern 1331b of the first active layer 1231 in the third contact hole CH3.

Accordingly, the first electrode 1280, the first conductive layer 1215, and the first active layer 1231 can be electrically connected to each other.

The repair pattern 1281 can be disposed to be spaced apart from the first electrode 1280.

The repair pattern 1281 can be disposed on one or more portions of the top surface of the fifth insulating layer 1305 and can be disposed along the fourth contact hole CH4.

The repair pattern 1281 can contact a portion of the top surface of the second electrode pattern 1242 through the fourth contact hole CH4.

When a defect occurs in a subpixel where the second electrode pattern 1242 is disposed, a welding process can be performed by irradiating a laser from the back of the substrate 1200 toward the second electrode pattern 1242.

At this implementation, the second electrode pattern 1242 and the first active layer 1231 disposed under the second electrode pattern 1242, which are spaced apart from each other, can contact each other, and thereby, the second electrode pattern 1242 and the first active layer 1231 can be electrically connected to each other.

A source voltage can be applied to the repaired subpixel from another subpixel to which the repair pattern 1281 is connected.

A reflection reduction layer RRL can be disposed on the substrate 1200.

A buffer layer BUF can be disposed on the reflection reduction layer RRL.

The buffer layer BUF can include a first buffer layer BUF1 including a transparent material and configured to have a flat surface, and a second buffer layer BUF2 disposed on the first buffer layer BUF1.

The reflection reduction layer can be disposed on the substrate 300. The buffer layer can be disposed on the reflection reduction layer. As the reflection reduction layer is disposed on the substrate, corresponding reflectance can be reduced. In addition, the thickness of the reflection reduction layer can be relatively thin in the repair area RA, and therefore, visibility of the repair area RA can be ensured.

The example embodiments described above will be briefly described as follows.

According to the example embodiments described herein, a display device can be provided that includes a substrate including a light emitting area and a circuit area, a reflection reduction layer including an open area corresponding to the light emitting area and a reflection prevention area outside of the open area, a buffer layer disposed on the reflection reduction layer, and an emission layer disposed on the buffer layer.

In one or more aspects, the display device can further include a repair area disposed in the circuit area, and the reflection reduction layer can include a first part that is an outer area of the repair area, and a second part that corresponds to the repair area and has a thickness less than the first part.

In one or more aspects, the buffer layer can include a first buffer layer including a transparent material and configured to have a flat surface, and a second buffer layer disposed on the first buffer layer.

In one or more aspects, the buffer layer can be configured with a single layer.

In one or more aspects, the buffer layer can include at least one of silicon dioxide (Sio2) or silicon nitride (SiNx)

In one or more aspects, a thickness of the buffer layer can be 0.5 micrometers or more.

In one or more aspects, a thickness of the reflection reduction layer can be 0.1 micrometer to 0.5 micrometer, and a transmittance of the reflection reduction layer corresponding to the repair area can be 50% or more.

In one or more aspects, the repair area can be visible from outside of the display device.

In one or more aspects, an optical density of the reflection reduction layer corresponding to the repair area can be 0.1 to 0.6.

In one or more aspects, the display device can further include a plurality of subpixels disposed over the substrate, and the reflection reduction layer can be disposed in a light emitting area of a first subpixel among the plurality of subpixels, and be not disposed in a light emitting area of a second subpixel.

In one or more aspects, the first subpixel can be a white subpixel.

In one or more aspects, an optical density of the reflection reduction layer corresponding to the light emitting area of the first subpixel can be 0.1 to 0.6.

In one or more aspects, the display device can further include a color filter disposed between the emission layer and the substrate.

In one or more aspects, the reflection reduction layer can include a black property.

In one or more aspects, the reflection reduction layer can be configured with a mixture of red and blue properties.

In one or more aspects, the reflection reduction layer can have high heat resistance characteristics.

According to the one or more aspects described herein, a display device can be provided that is capable of reducing the reflection of light without applying a polarizer.

According to the one or more aspects described herein, a display device can be provided that is capable of reducing the reflection of light and ensuring visibility of a repair area without applying a polarizer.

According to the one or more aspects described herein, a display device can be provided that is capable of being driven at low power as a polarizer with low transmittance is not applied.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display device comprising:
a substrate comprising a light emitting area and a circuit area;
a reflection reduction layer comprising an open area corresponding to the light emitting area and a reflection prevention area outside of the open area;
a buffer layer disposed on the reflection reduction layer; and
an emission layer disposed on the buffer layer.

2. The display device of claim 1, further comprising:
a repair area disposed in the circuit area,
wherein the reflection reduction layer further comprises:
a first part that is an outer area of the repair area; and
a second part that corresponds to the repair area and has a thickness less than the first part.

3. The display device of claim 2, wherein the buffer layer comprises:
a first buffer layer comprising a transparent material and configured to have a flat surface; and
a second buffer layer disposed on the first buffer layer.

4. The display device of claim 2, wherein the buffer layer is configured as a single layer.

5. The display device of claim 4, wherein the buffer layer comprises at least one of silicon dioxide (SiO₂) and silicon nitride (SiNx).

6. The display device of claim 4, wherein a thickness of the buffer layer is equal to or greater than approximately 0.5 micrometer.

7. The display device of claim 2, wherein a thickness of the reflection reduction layer is approximately 0.1 micrometer to 0.5 micrometer, and a transmittance of the reflection reduction layer corresponding to the repair area is equal to or greater than approximately 50%.

8. The display device of claim 2, wherein the repair area is visible from an outside of the display device.

9. The display device of claim 2, wherein an optical density of the reflection reduction layer corresponding to the repair area is approximately 0.1 to 0.6.

10. The display device of claim 1, further comprising:
a plurality of subpixels disposed over the substrate,
wherein the reflection reduction layer is disposed in a light emitting area of a first subpixel among the plurality of subpixels, and is not disposed in a light emitting area of a second subpixel among the plurality of subpixels.

11. The display device of claim 10, wherein the first subpixel is a white subpixel emitting white color light.

12. The display device of claim 10, wherein an optical density of the reflection reduction layer corresponding to the light emitting area of the first subpixel is approximately 0.1 to 0.6.

13. The display device of claim 1, further comprising:
a color filter disposed between the emission layer and the substrate.

14. The display device of claim 1, wherein the reflection reduction layer comprises a black property.

15. The display device of claim 1, wherein the reflection reduction layer is configured to comprise a mixture of red and blue properties.

16. The display device of claim 1, wherein the reflection reduction layer is heat resistance to a predetermined temperature or greater.

17. The display device of claim 1, wherein the display device excludes a polarizer.

18. The display device of claim 1, wherein thicknesses of the reflection reduction layer varies in the circuit area,
wherein thicknesses of the buffer layer varies in the circuit area, and
wherein a combined thickness of the reflection reduction layer and the buffer layer is constant in the circuit area.

19. A display device comprising:
a substrate including a light emitting area and a circuit area;
a reflection reduction layer having a first area with a first optical density, and a second area with a second optical density different from the first optical density;
a buffer layer disposed on the reflection reduction layer; and
an emission layer disposed on the buffer layer.

20. The display device of claim 19, wherein a thickness of the first area is different from a thickness of the second area.
